(19) United States
(12) Patent Application Publication
(10) Pub. No.: US 2026/0177483 A1
(43) Pub. Date: Jun. 25, 2026

(54) METHOD AND SYSTEM FOR AUTOMATED FEATURE INSPECTION AND ALIGNMENT IN SEMICONDUCTOR FABRICATION

(71) Applicant: Onto Innovation Inc., Wilmington, MA (US)

(72) Inventors: Jian Ding, Methuen, MA (US); Noah Bock, Blaine, MN (US); Christopher J. Voges, Wilmington, MA (US); David Papp, Bend, OR (US)

(73) Assignee: Onto Innovation Inc., Wilmington, MA (US)

(21) Appl. No.: 19/001,226

(22) Filed: Dec. 24, 2024

(51) Int. Cl. G01N 21/64; G01N 21/21; H01L 21/66; H01L 21/67

(52) U.S. Cl. CPC G01N 21/6402; G01N 21/21; H10P 72/0616; H10P 74/203; G01N 2201/06113; G01N 2201/0683

(57) ABSTRACT

The present application provides a method and system for automated inspection of a microfabricated feature on a substrate. The disclosure utilizes manipulating laser polarization in combination with the excitation and emission process, in inspection applications. The application specifically discloses selecting the polarization of the laser light by adjusting a polarization manipulator or a quarter-waveplate and/or a half waveplate between the laser source and the substrate to impart polarization to the laser light. The polarization impacts using a polarization selected to improve fluorescence emission of certain features on a substrate. The selection can be made prior to run time or dynamically during the inspection tool runtime. If the polarization is not specifically selected, then the microfabricated features may not emit much fluorescence.

### TECHNICAL FIELD

The present disclosure is directed to an automated system for inspecting and aligning features, and more particularly to a method of automating the inspection of microfabricated features on substrates.

### BACKGROUND

The semiconductor fabrication process requires precise and accurate inspection methods to ensure the quality, yield and functionality of the produced components. As the Redistribution Layer (RDL) line spacing gets smaller and smaller, especially when a group of RDL lines are in parallel formation, the efficiency with which the laser excites the dielectric materials in between the metal lines are strongly dependent of the polarization of the laser. This often results in large variation in the image brightness which can reduce the accuracy of defect detection. Thus, there is a need for advanced methods of laser polarization manipulation to enhance fluorescence imaging capabilities, especially when the line spacing gets smaller and smaller, when a group of RDL lines are in parallel formation, particularly for high-precision inspection applications in semiconductor fabrication. These improvements could lead to better resolution, higher sensitivity, and more accurate defect analysis in modem semiconductor devices.

### SUMMARY

The present application provides a method and system for automated inspection of a microfabricated feature on a substrate. The disclosure utilizes manipulating laser polarization in combination with the excitation and emission process, in inspection applications. The application specifically discloses selecting the polarization of the laser light by adjusting a polarization manipulator or a quarter-waveplate and/or a half waveplate between the laser source and the substrate to impart polarization to the laser light. The polarization impacts using a polarization selected to improve fluorescence emission of certain features on a substrate. The selection can be made prior to run time or dynamically during the inspection tool runtime. If the polarization is not specifically selected, then the microfabricated features may not emit much fluorescence.

One aspect of the present disclosure provides a method of automated inspection of a microfabricated feature on a substrate. The method comprising of, loading the substrate into an inspection tool having a laser source; selecting a polarization of laser light emitted by the laser source based on microfabricated feature; irradiating the microfabricated feature with the laser light from the laser source; and use the collected fluorescence emission emitted by the microfabricated feature in response to being irradiated with the laser light from the laser source to form an image of the microfabricated features.

Another aspect of the present technology provides a computer readable storage medium storing processor-executable instructions configured to, when executed by at least one processor, cause performance of a method of automated inspection of a microfabricated feature on a substrate, the method comprising: loading the substrate into an inspection tool having a laser source; selecting a polarization of laser light emitted by the laser source based on the microfabricated feature; irradiating the microfabricated feature with the laser light from the laser source; and use the collected fluorescence emission emitted by the microfabricated feature in response to being irradiated with the laser light from the laser source to form an image of the microfabricated features.

Yet another aspect of the present technology provides an apparatus for automated inspection of a microfabricated feature on a substrate. The apparatus comprising a stage for holding the substrate; a laser source; control circuitry configured to: select a polarization of laser light emitted by the laser source based on the microfabricated feature; and control irradiation of the microfabricated feature with the laser light from the laser source; and a detector configured to use the collected fluorescence emission emitted by the microfabricated feature in response to being irradiated with the laser light from the laser source to form an image of the microfabricated features.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Additional aspects, features, and/or advantages of examples will be set forth in part in the description which follows and, in part, will be apparent from the description, or may be learned by practice of the disclosure.

### BRIEF DESCRIPTION OF THE DRAWINGS

Non-limiting and non-exhaustive examples are described with reference to the following figures.

FIG. 1 depicts a method for automated inspection of a microfabricated feature on a semiconductor packaging panel, in accordance with an embodiment of the disclosure.

FIG. 2A is an image depicting an example redistribution layer (“RDL”) bridging defect on a layer of a multilayer semiconductor substrate, in accordance with an embodiment of the disclosure.

FIG. 2B is an image depicting an example defect in the form of a broken RDL conduit line on a layer of a semiconductor substrate, in accordance with an embodiment of the disclosure.

FIG. 3 schematically depicts changing polarization of the laser light using a half-waveplate, in accordance with an embodiment of the disclosure.

FIG. 4 schematically depicts changing polarization of the laser light using a quarter-waveplate, in accordance with an embodiment of the disclosure.

FIG. 5 schematically depicts changing polarization of the laser light using a half-waveplate and quarter-waveplate, in accordance with an embodiment of the disclosure.

FIG. 6 schematically depicts an apparatus for automated inspection of a microfabricated feature on a semiconductor packaging panel, in accordance with an embodiment of the disclosure.

FIG. 7 schematically depicts an example computer subsystem configured to automatically inspect a microfabricated feature on a semiconductor packaging panel, in accordance with an embodiment of the disclosure.

### DETAILED DESCRIPTION

In fluorescence imaging, a laser is used to excite fluorophores or specific features within the semiconductor material, resulting in the emission of light at a different wavelength. The emitted light can be detected and analyzed to gain information about the structural and material integrity of the sample. However, one challenge in fluorescence-based inspection is controlling and optimizing the polarization of the laser beam. Polarization manipulation can significantly affect the efficiency of fluorescence excitation and detection, particularly in structured or anisotropic materials, such as those used in semiconductor layers. Depending on the features, the fluorescence imaging might not produce much fluorescence, making it difficult to inspect the features. By manipulating the polarization of a laser shining on the substrate, the fluorescence excitation and emission can be enhanced.

The microfabricated features are typically, a plurality of redistribution layers (RDLs), with closely spaced RDL lines (conductive traces), pads, or other circuitry or transistors. In general terms, the present disclosure relates to improvements in laser polarization of features on a substrate such as a panel or wafer. A wafer is generally a flat discoid object of varying diameter. Wafers are generally formed of a semiconductor material such as silicon, gallium arsenide, and the like, though in some instances Glassell composite materials such as epoxy can be used. In some embodiments, the semiconductor wafer can include an orientation structure such as a notch, mark, flat or other structure. Such semiconductor wafers frequently have a diameter of between about 200 mm and about 300 mm, but other sizes of semiconductor wafers are also common.

A panel is generally a flat object made of semiconductor materials, glass, or composite materials. Panels typically have a rectangular or square shape and come in a variety of sizes. In some embodiments, the panel can be in the form of a copper core laminate (CCL) panel, a glass panel substrate, or other panel constructed of soda-lime glass treated with one or more special coatings to improve the adhesion and uniformity of deposited materials.

A substrate can be any flat material that is used in semiconductor or related manufacturing. The substrate can be a panel or a wafer depending on the circumstances. In some embodiments, either a wafer or a panel can serve as a base upon one or more layers of material are applied and processed to create a multilayered substrate. For example, the one or more layers can include one or more redistribution layers, which may include conductive traces, interspaced between insulative, dielectric layers. Through holes can be defined in the wafer or a panel to enable communication between layers applied to opposing major surfaces of the wafer or a panel.

Polarization generally refers to the orientation of the electric field vector of a laser beam as it propagates. In a linear polarized laser light, the electric field oscillates in a specific direction, which can be manipulated as per the application. In some embodiments, polarized lasers are used to enhance defect detection by exploiting the interaction of polarized light with a substrate. When a polarized laser light is directed at the substrate, defects on the panel causes variations in intensity, phase, or wavelength of the reflected light, which is further analyzed to identify and characterize the defect present on the substrate with greater sensitivity and precision.

Fluorescence emission generally refers to the light emitted by a dielectric (fluorescent) material on a substrate when it is exposed to light of a specific wavelength. The emitted fluorescent light generally has a longer wavelength than the incident light. In certain embodiments, an image sensor (or detector) captures the light emitted by the dielectric material to identify defects on the substrate. The resulting fluorescent emission is then analyzed to identify the type and location of defects, based on variations in intensity and contrast of the emitted light. Most of the metals do not give fluorescence light in the visible wavelength while a lot of the dielectric insulation materials do. Thus, the manufactured pattern metal line/pad pattern can be inspected using fluorescence from the dielectric materials.

Alignment of a microfabricated feature generally refers to position and orientation of the microfabricated feature like RDL lines on a substrate. In some embodiments an indication of alignment of microfabricated feature is received by the inspection tool for enhanced defect detection. The indication of alignment of microfabricated feature may be a visual representation of the characteristics of the microfabricated feature or may be a feature description detailing aspects like shape, dimension, and position, as obtained by usually microscope with Bright Field illumination. Collectively, these alignment indications enable precise detection of defects on the microfabricated feature, facilitating optimal defect detection and corrections.

In some embodiments, the substrate can include an array of repeated functional units, each of which can represent a portion of a substrate on which a given functional circuit is fabricated. For example, in one non-limiting example, the functional circuit can take the form of a central processing unit. In some embodiments, additional electrical components can be electrically coupled to the substrate to complete the functional unit. In other embodiments, the layered substrate itself can represent a completed functional unit.

Each of the functional units can then be cut from the substrate into (e.g., rectangular shaped) dies, wherein each die contains one copy of the functional circuit. To avoid damage to the dies, in some embodiments, a thin, non-functional spacing can be provided between dies, allowing for cutting (e.g., with a saw) of individual dies from a substrate without damaging the circuits. In this manner, a functional circuit can be batch manufactured on a single substrate. Once cut into individual dies, the dies can be applied to a printed circuit board for use in electronics.

As the fabrication process progresses, defects can occur in different layers in different packages. Such defects can include, for example, RDL bridging, RDL opens, dielectric breakdown, and so forth. Thus, the number of defects across the entire semiconductor substrate can increase as more layers are added. In addition, future layers can be impacted by defects occurring in earlier formed layers.

According to one aspect of the present disclosure, a method of automated inspection of a microfabricated feature on a substrate is disclosed. The method comprises of loading the substrate into an inspection tool having a laser source, selecting a polarization of laser light emitted by the laser source, based on the microfabricated features on the substrate. The method as per the present disclosure further comprises, irradiating the microfabricated feature with the laser light from the laser source and collecting fluorescence emission emitted by the microfabricated feature in response to being irradiated with the laser light from the laser source. As per the present disclosure, the polarization of the laser light maybe selected to be elliptical polarization, circular polarization or to substantially align with the microfabricated feature.

The RDL (Redistribution Layer) lines are conductive traces utilized to redistribute electrical signals. The RDL lines can be made of metals like copper or aluminum. The metals are often combined with barrier layers like titanium or tantalum, as well as gold (Au) for high-reliability applications due to their corrosion resistance properties. The RDL lines are closely spaced, ranging from 0.5 to 30 microns, more preferably less than 20 microns to optimize interconnect density and facilitate efficient signal routing.

The space between the RDL lines is interleaved with dielectric materials (insulation materials) to ensure electrical isolation and prevent short circuits. Dielectric materials typically used are polymers with a lower k value (dielectric constant) like benzocyclobutene (BCB) and polyamide or other dielectric materials like silicon dioxide. In some embodiments, the dielectric materials are organic polymers like polyamide with fluorescent properties. Furthermore, the insulation materials may be any photo-resist material which fluoresces upon absorbing light at an excitation wavelength. In an alternative embodiment, any fluorescent material may be added to the non-fluorescent dielectric material to produce a fluorescence effect. The method of automated inspection of closely spaced parallel RDL lines enables the detection of minute defects that could impact the performance of the substrate, contributing to higher yield rates in the manufacturing process.

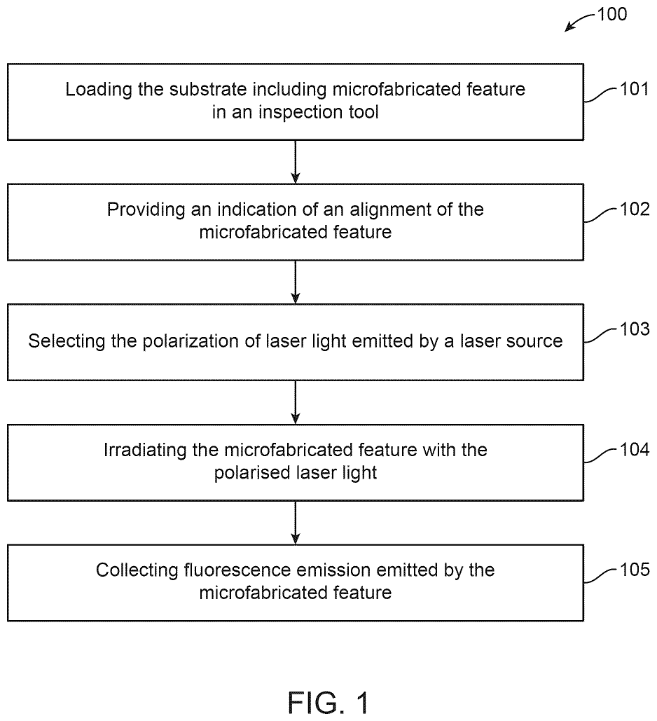

Referring to FIG. 1, the process flow of automated inspection of a microfabricated feature on a substrate is disclosed. The process comprises step 101, loading the substrate into an inspection tool having a laser source. The substrate comprises a microfabricated feature, wherein the microfabricated feature comprises a plurality of RDL lines arranged on fluorescent dielectric material, which is further inspected by the inspection tool for defect detection on the RDL lines from the fluorescence images.

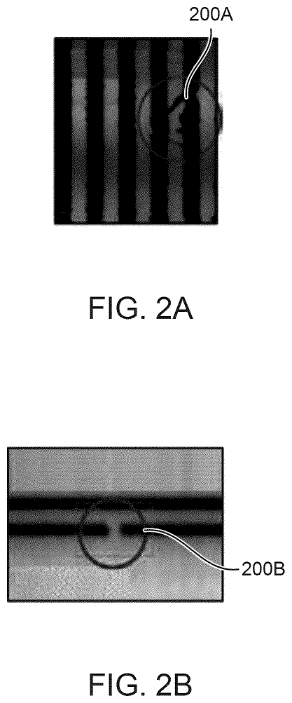

In some embodiments, the loaded substrate, inspected by the inspection tool, may comprise at least one or more defects on the RDL lines as shown in FIGS. 2A and 2B. The defects may include but are not limited to line bridging, bottom seed bridging, open lines, dielectric breakdown, etch residue, corrosion or any type of contamination. FIG. 2A depicts an example of the RDL bridging defect 200A on a layer of a multilayer substrate, wherein the RDL bridging is a defect which occurs due to the presence of a short circuit between two adjacent redistribution layer (RDL) lines. Similarly, referring to FIG. 2B, an example defect in the form of a broken RDL line 200B on a layer of a substrate is depicted. A broken RDL line refers to a discontinuity in the metal traces of a substrate, which can arise from manufacturing defects such as improper etching, physical stress, or thermal cycling, leading to loss of electrical connectivity.

As depicted in FIG. 1, the method of automated inspection of a microfabricated feature on a substrate further comprises step 102, determining an indication of an alignment of the microfabricated feature. In one embodiment, the indication of an alignment of the microfabricated feature comprises an image of the microfabricated feature. The image received by the inspection tool may be an image taken by a camera attached to a microscope or Electron microscope images, X-ray images, optical or thermal images, which provide an accurate alignment indication of the RDL lines for optimized defect detection. The method of automated inspection comprising of receiving an image of the microfabricated feature, enables visual confirmation of alignment of the microfabricated feature (RDL lines), which can be more intuitive and user-friendly for operators, potentially reducing the likelihood of human error.

In a further embodiment, the indication of an alignment of the microfabricated feature further comprises a feature description of the microfabricated feature. The feature description of the RDL lines loaded into the inspection tool may be, but is not limited to, spatial features like position and spacing, geometrical features like shape and dimension, optical features like reflectivity and contrast, overlay measurements or via position. As per the present disclosure, the feature description of the RDL lines comprises of the orientation of the RDL lines at a particular location. The step 102 of determining feature description of the microfabricated feature helps in identifying, if the RDL lines are vertical, horizontal or at any angle and adjusting the polarization to analyze all RDL lines present on the substrate, for optimized inspection of the substrate. The use of preloaded feature descriptions aids in streamlining the inspection process by reducing the need for manual input or adjustments, thereby minimizing downtime and enhancing throughput in high-volume production environments.

The determining step can be performed at recipe creation, by reviewing the CAD (computer aided drawing) files, or by inspection depending on the embodiment. If done at recipe creation, a computer can determine the aspects of the microfabricated features, such as the alignment. In analyzing the recipe, the CAD file(s), or an inspection image, it can be determined what the polarization of the light is to optimize the fluorescence.

The method as depicted in FIG. 1, further comprises step 103, selecting a polarization of laser light emitted by the laser source. The polarization selection in some embodiments is performed based on the microfabricated features on the substrate which is acquired from the indication of alignment received in step 102. The selected polarization of laser light in an embodiment maybe any type of polarization selected from but not limited to linear polarization, circular polarization, elliptical polarization or any polarization. The type of polarization is selected to ensure that all types of microfabricated feature is analyzed during inspection, irrespective of its orientation and location, thereby achieving improved defect detection by the inspection tool.

As per present disclosure, the method of automated inspection of a microfabricated feature on a substrate comprises, loading the substrate into an inspection tool having a light source. The light source in some embodiments is a laser source that directs light to the substrate at one or more angles of incidence, which may include one or more oblique angles and/or one or more normal angles. The laser source may be but is not limited to a semiconductor laser, solid state laser, harmonic generation of a solid state laser or linearly polarized ion laser. Furthermore, the laser light emitted by the laser source is polarized based on the microfabricated features on the substrate.

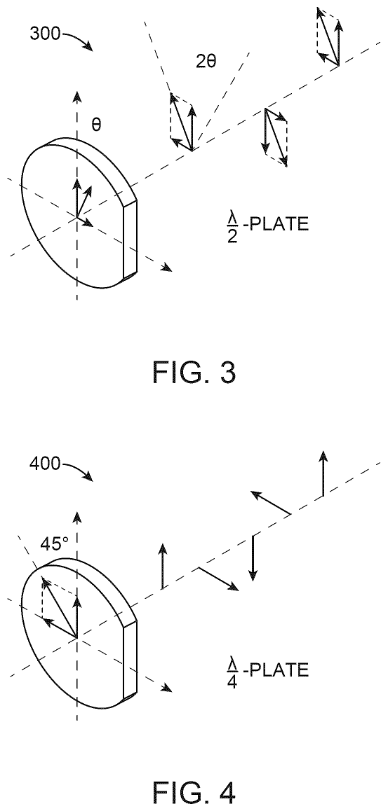

Laser light polarization is achieved using various optical components (elements) like waveplates or wave retarders. The wave plates can be half-waveplates and quarter-waveplates, for achieving desired laser light polarization. The use of a combination of a quarter-waveplate and/or a half-waveplate provides flexibility in selecting the desired polarization of the laser light, allowing for customization based on the specific requirements of the inspection. Half waveplates are used to cause the rotation of the polarization plane of a linearly polarized incident laser light. Referring to FIG. 3, of the present disclosure a laser light wave is normally incident on a waveplate, its plane of polarization forms an angle θ with respect to the first axis. The incident laser light is resolved into two orthogonal components (a first component and a second component) along the two axes. While traversing through the waveplate, the first component experiences a phase shift of half a wavelength, resulting in it being 180° out of phase with the corresponding second component as shown in 300 of FIG. 3. This means that while the first component reaches a maximum, the second component is also at a maximum but directed along the negative second axis. Consequently, the overall effect is that the polarization of the wave is rotated through an angle of 2θ, regardless of whether the incident wave is oriented at an angle θ to the first or the second axis.

A quarter-waveplate is used to achieve circular polarization of a linearly polarized incident light wave. This is achieved by adjusting the orientation of the waveplate to equally excite both the orthogonal components of the incident light. As depicted in FIG. 4, of the present disclosure the laser light is incident on the quarter-waveplate at an angle of 45°. At a point along the optical axis where the first component is at maximum, the second component is retarded by a quarter-wave or 90° in phase. At another point along the optical axis, the two components are equal in magnitude, with the first component decreasing while the second component is increasing. Further along the optical axis, the second component reaches its maximum while the first component is zero. This causes the incident laser light wave to rotate circularly within a period of just one wavelength, thereby achieving circular polarization as shown in 400 of FIG. 4.

In certain cases, when the laser light is incident on the quarter-waveplate at an angle other than 45°, the phase difference between the first and second components is not exactly a quarter-wave or 90°. The first and second components of the incident laser light traces out an elliptical path as it propagates generating elliptically polarised light. The angle of elliptical path generated is a function of magnitude of phase shift, and the tilt angle of the ellipse depends on the tilt angle of the incident laser light relative to the waveplate. Elliptical polarization is a more flexible type of polarization as it encompasses both linear and circular polarization as specific cases based on the angle of the incident laser light.

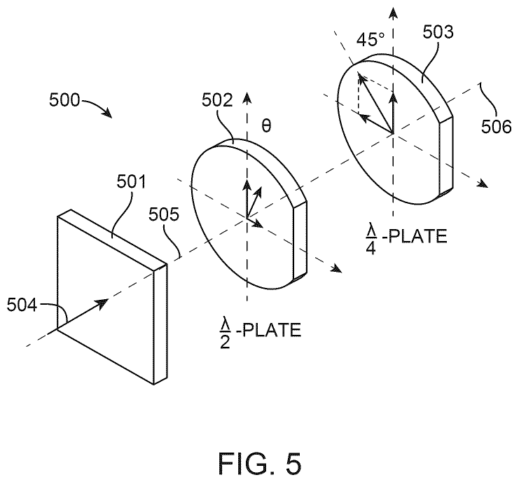

FIG. 5 illustrates an embodiment where a half-waveplate and a quarter-waveplate are used together to polarize the light. The optical component arrangement 500 of FIG. 5, comprises of linear polarizer 501, half-waveplate 502 and a quarter-waveplate 503 arranged to adjust the polarization of the incident laser light. The linear polarizer confines both the orthogonal components of the incident laser light 504 to align in a selected direction such that there is no phase difference between the first and second components. The linearly polarised light 505 is then passed through a half-waveplate which introduces a 180° phase shift between the first and second components introducing a rotation or inversion in the linear polarization of the incident laser light. The half-waveplate is followed by a quarter-waveplate which introduces 90° phase shift between the two components of the laser light, thereby converting the linearly polarized light into light 506, a generally elliptically polarized light with any predetermined aspect ratio and orientation.

A phase shift other than 900 is introduced in the linearly polarized light by rotating the quarter-waveplate generating an elliptically polarized light 506. As per the present disclosure, by adjusting the orientation of the half-waveplate 502 and quarter-waveplate 503 present in the optical component arrangement 500, different types of polarization(s) are introduced in the incident laser light 504. For example, the orientation of the waveplates can be adjusted to change the polarization of the light. The orientation can be changed by, for example, rotating the waveplate. This arrangement can be used to manipulate the polarisation of light, which beneficially allows for obtaining a clearer image of the RDL lines on the substrate. Furthermore, the elliptically polarized light interacts differently with any defect present in RDL lines which enables easier differentiating between normal RDL line features and RDL line defects, thereby facilitating more accurate and effective inspection of the RDL lines irrespective of its orientation.

In an example embodiment of the present disclosure, the optical component arrangement 500 comprising of linear polarizer 501 for setting the initial polarization, half-waveplate 502 for rotating and adjusting the polarization direction and a quarter-waveplate 503 to further convert the polarization into circular or elliptical polarization. As the laser light 504 is incident from the lower-left corner to the upper-right corner of the substrate, the half-waveplate 502 aligns the polarization into a single plane and the quarter-waveplate 503 is rotated to precisely control the polarization shape (elliptical or circular). The waveplate orientation is adjusted by rotation based on the alignment of the microfabricated features at various locations on the substrate. If the RDL lines are vertical or horizontal, the quarter-waveplate 503 is rotated to generate polarized laser light which analyses these vertical or horizontal lines. If the RDL lines are aligned at an angle, the quarter-waveplate 503 is rotated to generate polarized laser light having a shape which analyses these RDL lines present at an angle. In a most preferred embodiment of the present disclosure, a combination of waveplates (half-waveplate and quarter-waveplate) beneficially aids in providing precise control over the polarization of the incident laser light 504, thereby ensuring optimal inspection is performed at all parts of the substrate, regardless of the alignment of the microfabricated feature.

In an alternate embodiment, the linearly polarized laser light may be polarized to substantially align with RDL lines by inserting only a half-waveplate between the laser source and the substrate. The half-waveplate manipulates the polarization of the laser source by providing a 180-degree phase shift, enabling precise control over the polarization direction of emitted laser light. When the laser light passes through the half-waveplate, its polarization is rotated by twice the angle of incidence relative to the waveplates optical axis. The polarization of the laser light is substantially aligned to the direction of the RDL lines on the substrate, by adjusting the orientation of the half-wave plate. The selection of laser light polarization tailored to substantially align with the microfabricated feature enhances the contrast and detection sensitivity during inspection, leading to improved defect identification.

In another alternate embodiment, the linearly polarized laser light emitted by the laser source is circularly polarized by inserting only a quarter-waveplate between the laser source and the substrate. The quarter-wave plate introduces a specific phase shift between the two orthogonal components of the incident laser light. The quarter-wave plate produces a precise phase shift of one-quarter of a wavelength, thereby achieving an elliptical polarization. When the optical axis of the ¼ wave plate is at 45 degrees with respect to the linear polarization direction, both the orthogonal components of the laser light emerging out of the quarter-waveplate rotates, either clockwise or counterclockwise direction, forming circular polarization. The method of automated inspection by utilizing circularly polarized light can minimize the impact of feature orientation, allowing for consistent inspection results across various feature geometries and orientations.

As depicted in FIG. 1, the method of automated inspection of a microfabricated feature on a substrate further comprises step 104, irradiating the microfabricated feature with the laser light from the laser source. The polarized laser light is used to irradiate the substrate having RDL lines causing dielectric material between the RDL lines to produce fluorescence. Additionally, wavelength of the laser source is chosen to match the absorption spectrum of the fluorescent dielectric material for maximizing interaction of the laser light with the dielectric material.

The interaction of laser light energizes the fluorescent materials present in the substrate, causing them to emit light at a longer wavelength, resulting in fluorescence. In areas of substrate with RDL lines that are free from defects, the emitted fluorescence is uniform in intensity and color. However, in defect areas, the fluorescence emission characteristics change, due to the presence of bridging, cracks or open lines. This causes disruption in the uniformity of fluorescence emitted by the dielectric material, leading to reduced fluorescence intensity as the light may scatter or be absorbed differently in defect areas.

The method of automated inspection of a microfabricated feature on a substrate further comprises step 105, collecting fluorescence emission emitted by the microfabricated feature in response to being irradiated with the laser light from the laser source. The method comprises, collecting fluorescent emissions from the substrate using a detector assembly, which is then analyzed to identify defects in the microfabricated features. Areas of the substrate containing redistribution (RDL) lines which emits fluorescence uniform intensity and color are identified as defect-free. Conversely, areas where the fluorescence characteristics show variations, indicative of defects such as bridging, cracks, or open lines, are identified as defect areas. Furthermore, the method enables the precise identification of location and type of defect based on this intensity variation of the emitted fluorescence.

In some embodiments, an optical image detector assembly comprise one or more image sensors and one or more optical elements to collect fluorescence emission emitted by the microfabricated feature in response to being irradiated with the laser light from the laser source. The image sensors present in the optical image detector assembly are any one or a combination of time delay integration (TDI) camera, area scan camera, hyperspectral camera or other sensor type (e.g., one that captures color information) as desired. These sensors may be of a CCD or CMOS arrangement, as desired. Further, the optical elements present in the optical image detector assembly is any one or a combination of lenses, collimators, beam splitters, filters, etc. for focusing, collecting and collimating of light.

The method 100 disclosed in accordance with the present disclosure, is beneficial for identifying defects at a microscopic level by combining both excitation and emission process by utilizing the laser polarization. For example, benefits include precise defect localization, performing non-destructive testing of substrate or wafer without physical alteration or damage, better control of fabrication quality, reducing the occurrence of yield-reducing defects, etc.

According to another aspect of the present disclosure, an apparatus (or a system) for automated inspection of a microfabricated feature on a substrate is disclosed. The apparatus comprises a stage, a laser source and a control circuitry. The control circuitry is configured to select a polarization of laser light emitted by the laser source based on the microfabricated features on the substrate. This can be done at runtime dynamically or prior to running (e.g., in recipe creation or CAD file analysis). The polarization of laser light emitted by the laser source is selected, either to be circularly polarized, elliptically polarized or to either substantially align with the microfabricated feature and control irradiation of the microfabricated feature with the laser light from the laser source. The apparatus further comprises of a detector assembly configured to collect fluorescence emission emitted by the microfabricated feature in response to being irradiated with the laser light from the laser source.

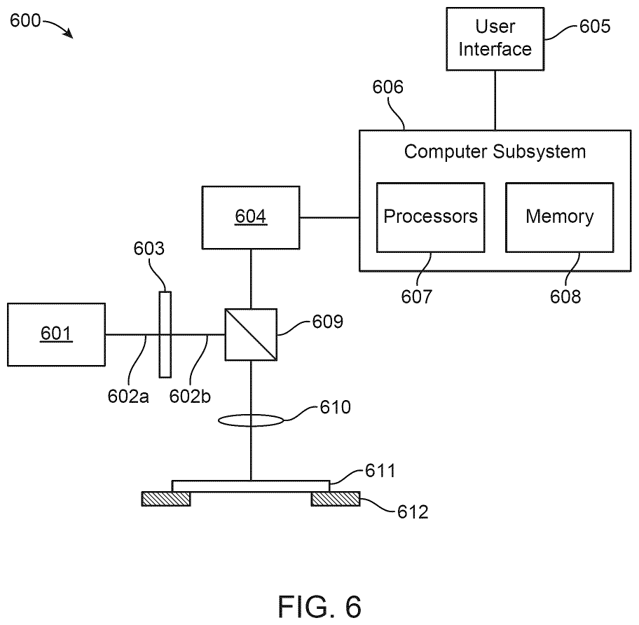

Referring to FIG. 6, an apparatus 600 for automated inspection of a microfabricated feature on a substrate is disclosed. The apparatus comprises of a stage 612 for holding the substrate 611 to be inspected. As per the present disclosure the stage is preferably moving, and the movement of the stage may be accomplished by means for moving the stage. Such means for moving the stage may include, for example, one or more servo motors, stepper motor(s), actuators, or other means for moving the stage. Furthermore, the stage movement may be guided by system coordinates, thus moving the stage relative to optical elements of the apparatus 600 precisely.

The apparatus 600 for automated inspection of a microfabricated feature on the substrate further comprises of laser source 601. The laser source 601 in an embodiment directs light to the substrate 611 at one or more angles of incidence, which may include one or more oblique angles and/or one or more normal angles. The oblique angle of incidence may include any suitable oblique angle of incidence, which may vary depending on, for instance, characteristics of the substrate 611. Laser source 601 may emit light in a single wavelength or a narrow band of wavelengths (e.g. monochromatic) or across a wider band of wavelengths that is exclusive of the wavelengths of fluorescent light that is of interest.

As depicted in FIG. 6, the laser light 602a emitted by the laser source 601 is incident on an optical component (or element) arrangement 603, which introduces a desired type of polarization to the laser light 602a and generates a polarized light 602b. Optical component 603 can be a polarization manipulator. The polarization manipulator can include multiple elements such as half-waveplate, a quarter-waveplate, and a polarization plate. The polarization manipulator can adjust the polarization of the laser light 602a into elliptically polarized, circularly polarized, or linearly polarized, for example. The polarized light 602b is reflected by a beam splitter 609 and directed towards the substrate 611 through an objective lens 610. As per present disclosure, the microfabricated feature comprises a plurality of substantially parallel lines separated by a spacing of less than approximately 20 microns, but could be less than 10 microns, less than 5 microns, or less than 2 microns. The spacing could even be less than a micron. The plurality of substantially parallel lines on the substrate 611 are RDL lines with metal traces and fluorescent dielectric materials. When the laser light strikes the RDL lines present on the substrate 611, it causes the dielectric material to fluoresce.

The beam splitter 609 in an embodiment is a dichroic splitter that works by reflecting light at one range of wavelengths and passing light at another range of wavelengths. The beam splitter may in some embodiments, be set up as a long pass filter, a short pass filter, or a band pass filter. As per present disclosure, the beam splitter 609 passes the fluorescence emission emitted from the substrate 611, while reflecting the incident laser light. The beam splitter 609 reflects the laser light from the optical component arrangement 603 onto the substrate 611 through an objective lens 610. Further, the fluorescence emission that is emitted from dielectric material on the substrate 611 in the direction of the beam splitter 609 is transmitted through the beam splitter 609 towards the detector assembly 604 for defect detection of the RDL lines.

Further referring to FIG. 6, it is depicted that the objective lens 610 directs the laser light reflected from the beam splitter 609 onto the substrate 611. The objective lens aids in achieving high spatial resolution which is crucial in detecting minute defects present in the RDL lines. Further, the objective lens 610 collects the fluorescence emission emitted by the fluorescent material present in the RDL lines, in response to being irradiated with the laser light from the laser source. The collected fluorescence emission is further directed through the beam splitter 609, towards the detector assembly 604, for defect detection.

The laser light 602a emitted by the laser source further generates a polarized light 602b, which maybe either circularly polarized, elliptically polarized or polarized to substantially align with the microfabricated feature of the substrate 611. The desired laser light polarization is achieved by inserting the optical component arrangement 603. The optical component arrangement 603 can include a linear polarizer, half-waveplate and a quarter-waveplate. The linear polarizer confines both the orthogonal components of the incident laser light 602a to align in a selected direction such that there is no phase difference between the first and second components. The linearly polarised light is then passed through a half-waveplate which introduces a 180° phase shift between the first and second components introducing a rotation or inversion in the linear polarization of the incident laser light. The half-waveplate is followed by a quarter-waveplate which introduces 900 phase shift between the two components of the laser light, thereby converting the linearly polarized light into circular polarized light 602b.

In some embodiments as per the present disclosure, a phase shift other than 90° is introduced in the laser light by rotating the quarter-waveplate generating an elliptically polarized light 602b. As per the present disclosure, by adjusting the orientation of the half-waveplate and quarter-waveplate present in the optical component arrangement 603, different types of polarization are introduced in the incident laser light 602a. This allows for obtaining a clearer image of the RDL lines on the substrate. The elliptically polarized light 602b enables easier differentiating between normal RDL line features and RDL line defects, thereby ensuring effective inspection of the RDL lines irrespective of its orientation.

In an alternative embodiment, optical component arrangement 603 comprises of only a half-waveplate which polarizes the laser light 602a to substantially align with the RDL lines on the substrate 611. The half-waveplate changes the polarization of the incident laser light by causing a 180-degree phase shift, which enables precise control over the polarization direction of emitted laser light. The polarization of the laser light, passing through the waveplate is rotated by twice the angle of incidence, relative to the waveplates optical axis, causing the polarization of the laser light to substantially align to the direction of the RDL lines on the substrate. When the polarization substantially aligns with the direction of the RDL lines, the intensity of the light that interacts with the RDL lines is maximized, which aids in detecting the slightest defects present on the substrate 611.

In another alternative embodiment, the optical component arrangement 603 comprises of only a quarter-waveplate, which circularly polarizes the incident laser light 602a. The quarter-wave plate introduces a specific phase shift of 90° between the two orthogonal components of the incident laser light causing the polarized light wave 602b emitted to rotate either in clockwise or counterclockwise direction, tracing out a circular path based on the phase shift, thereby achieving circular polarization.

The apparatus 600 as shown in FIG. 6, for automated inspection of a microfabricated feature on a substrate further comprises of detector assembly 604. In some embodiments, the detector assembly 604 comprises of one or more image sensors and one or more optical elements. The image sensors present in the optical image detector assembly is any one or a combination of time delay integration (TDI) camera, area scan camera, hyperspectral camera or other sensor type (e.g., one that captures color information), or CCD or CMOS arrangement as desired. The image sensor is configured to generate a fluorescence image corresponding to the collected fluorescence emission. This generated fluorescence image is further used for defect detection of the microfabricated features on the substrate 611.

The apparatus 600 (or a system) for automated inspection of a microfabricated feature on a substrate further comprises a control circuitry 606. The control circuitry 606 can be configured to select a polarization of laser light emitted based on the microfabricated features on the substrate. The selected polarization of laser light in an embodiment maybe any type of polarization selected from but not limited to linear polarization, circular polarization, elliptical polarization or any polarization that is substantially aligned with the RDL lines. The type of polarization is selected to ensure that all types of microfabricated feature is analyzed during inspection, irrespective of its orientation and location.

The control circuitry 606 of the apparatus 600 for automated inspection is configured to select the polarization of the laser light in dependence on an indication of an alignment of the microfabricated feature. In a preferred embodiment, the indication of an alignment of the microfabricated feature received by the control circuitry 606, comprises an image of the microfabricated feature. The image received by the inspection apparatus 600 may be an optical image, which provide an accurate alignment indication of the RDL lines for optimized defect detection.

In some embodiment as per the present disclosure, the indication of an alignment of the microfabricated feature received by the control circuitry 606, comprises a feature description of the microfabricated feature. The feature description of the RDL lines loaded into the inspection apparatus 600 may be but is not limited to spatial features like position and spacing, geometrical features like shape and dimension, optical features like reflectivity and contrast, overlay measurements or via position.

As per present disclosure, the apparatus 600 stores the feature description in the memory 608. During the inspection process at a particular location, when the vertical or horizontal RDL lines are encountered, based on the stored feature description, the apparatus 600 rotates the quarter-waveplate present in the optical component arrangement 603 to adjust the polarization of the laser light to inspect these vertical or horizontal lines. If the RDL lines are aligned at an angle, the apparatus 600 rotates the quarter-waveplate optical component arrangement 603 to generate a polarized laser light having a shape suitable for inspecting the RDL lines present at an angle. The combination of a half-waveplate and quarter-waveplate in optical component arrangement 603 allows for manipulation of the polarization of the laser light, ensuring that the most suitable type of polarization (linear, circular, or elliptical) is used for inspecting microfabricated features on the substrate 611.

The control circuitry 606 of the apparatus 600 for automated inspection is configured to control irradiation of the microfabricated feature with the laser light from the laser source. The control circuitry 606 interfaces with the laser source, allowing for precise control over parameters like intensity, duration, and pulsing. The control circuitry 606, positions the laser beam accurately over the substrate surface, either through motorized stages or by controlling the laser optics (e.g., focusing lens). Furthermore, the control circuitry 606 adjusts the power of the laser source to optimize irradiation energy, so as not to cause any damage while irradiating the substrate 611.

Further referring to FIG. 6, the control circuitry 606 is coupled to the detector assembly 604. The control circuitry 606 analyses the fluorescent image obtained from the image sensor present in the detector assembly 604 and identifies from the fluorescent image of the substrate 611 whether a defect is present in RDL lines. Areas of substrate with RDL lines where the emitted fluorescence is uniform in intensity and color, are identified by the control circuitry as defect free areas, while areas where the fluorescence emission characteristics change, due to the presence of bridging, cracks or open lines, are identified as defect areas. The control circuitry 606 identifies the location of defect based on this intensity variation of the emitted fluorescence. Furthermore, the control circuitry 606 identifies different types of defects, based on light scattered from or absorbed by the substrate during irradiation.

In a further embodiment, the control circuitry 606 may also comprise of control mechanisms (e.g., a stage and/or a robot), to coordinate automated handling and processing of the substrate. The control circuitry 606 controls the movement of the stage 612 or the stage can be controlled by a motion controller that may be separate from, but which works in conjunction with, control circuitry 606. An equipment front end module (EFEM) or other handler can be coupled to a separate control circuitry that coordinates the provision and removal of the substrate from the stage.

The control circuitry 606 in some embodiments is a computer subsystem that includes I/O facilities, a processor 607, memory 608, user interface 605 and optionally network capabilities that allow the controller 606 to be connected to other local or remote controllers or to a computer network over which instructions are received and data is sent. The control circuitry 606 may work in local mode, handling all operations on the local system or may distribute some of its functions to remote controllers.

According to another aspect of the present disclosure, a computer readable storage medium storing processor-executable instructions configured to, when executed by at least one processor, cause performance of a method of automated inspection of a microfabricated feature on a substrate, is disclosed. The method comprising, loading the substrate into an inspection tool having a laser source, selecting a polarization of laser light emitted by the laser source, based on the microfabricated features on the substrate. As per the present disclosure, the polarization of the laser light maybe selected to be elliptical polarization, circular polarization or to substantially align with the microfabricated feature. The method further comprising, irradiating the microfabricated feature with the laser light from the laser source and collecting fluorescence emission emitted by the microfabricated feature in response to being irradiated with the laser light from the laser source.

The phrase “computer readable storage medium” may include any medium that is capable of storing, encoding, or carrying instructions for execution by the processor and that cause the processor to perform any one or more of the techniques of the present disclosure, or that is capable of storing, encoding or carrying data structures used by or associated with such instructions. Non-limiting computer readable storage medium examples may include solid-state memories, and optical and magnetic media. Specific examples of massed computer readable storage medium may include: non-volatile memory, such as semiconductor memory devices (e.g., Electrically Programmable Read-Only Memory (EPROM), Electrically Erasable Programmable Read-Only Memory (EEPROM)) and flash memory devices; magnetic or other phase-change or state-change memory circuits; magnetic disks, such as internal hard disks and removable disks; magneto-optical disks; and CD-ROM and DVD-ROM disks

The computer readable storage medium storing processor-executable instructions configured to execute, the method of automated inspection of a microfabricated feature on a substrate is disclosed. The method comprising, loading the substrate comprising the microfabricated feature into a stage on an inspection tool, wherein the microfabricated feature is a plurality of RDL lines arranged on fluorescent dielectric material.

The method of automated inspection of a microfabricated feature on a substrate further comprising, receiving, by the inspection tool, an indication of an alignment of the microfabricated feature. In one embodiment, the indication of an alignment of the microfabricated feature might be determined from an image, a CAD file, or a recipe. The image received by the inspection tool may be an optical image, which provide an accurate alignment indication of the RDL lines for optimized defect detection.

In a further embodiment, the indication of an alignment of the microfabricated feature comprising a feature description of the microfabricated feature. The feature description of the RDL lines loaded into the inspection tool may be but is not limited to geometrical features like shape and dimension, spatial features like position and spacing, optical features like reflectivity and contrast, overlay measurements or via position.

The computer readable storage medium storing processor-executable instructions is further configured to execute the method of automated inspection of a microfabricated feature on a substrate comprising, selecting a polarization of laser light emitted by the laser source. The polarization selection is performed based on the received indication of alignment. Furthermore, the type polarization is selection in some embodiments is performed based on the microfabricated features on the substrate which is acquired from the indication of alignment received. The selected polarization of laser light in an embodiment maybe any type of polarization selected from but not limited to linear polarization, circular polarization, elliptical polarization or any polarization that is substantially aligned with the RDL lines.

An optical component (or element) arrangement comprising of linear polarizer for setting the initial polarization, half-waveplate for rotating and adjusting the polarization direction and a quarter-waveplate to further convert the polarization into circular or elliptical polarization is used for adjusting the polarization of the incident laser light emitted by the laser source. In accordance with present disclosure, as the laser light is incident from the lower-left corner to the upper-right corner of the substrate, the half-waveplate aligns the polarization into a single plane and the quarter-waveplate is rotated to precisely control the polarization shape (elliptical or circular). The waveplate orientation is adjusted by rotation based on the alignment of the microfabricated features at various locations on the substrate. If the RDL lines are vertical or horizontal, the quarter-waveplate is rotated to generate polarized laser light which analyses these vertical or horizontal lines. If the RDL lines are aligned at an angle, the quarter-waveplate is rotated to generate polarized laser light having a shape which analyses these RDL lines present at an angle. The optical component arrangement helps in adjusting the polarization based on the orientation of the microfabricated features in the area of the substrate being inspected, thereby ensuring that no particular feature is missed out, whether aligned horizontally, vertically, or at any angle.

The computer readable storage medium storing processor-executable instructions is further configured to execute the method of automated inspection of a microfabricated feature on a substrate comprising, irradiating the microfabricated feature with the laser light from the laser source. The polarized laser light is used to irradiate the substrate having RDL lines causing dielectric material between the RDL lines to produce fluorescence.

The computer readable storage medium storing processor-executable instructions is further configured to execute the method of automated inspection of a microfabricated feature on a substrate comprising, collecting fluorescence emission emitted by the microfabricated feature in response to being irradiated with the laser light from the laser source. As per present disclosure, the fluorescence emission is emitted by the dielectric material having fluorescent properties, present on the substrate. The fluorescent emission is collected by a detector assembly and analyzed by a control circuitry for defect detection in microfabricated feature. The control circuitry analyses the emitted fluorescence and identifies defect location and type based on intensity variations of the fluorescence emission reflected from the microfabricated feature.

The control circuitry is a collection of circuits implemented in tangible entities that include hardware (e.g., simple circuits, gates, logic, etc.). Circuitry membership may be flexible over time and subject to underlying hardware variability. Circuitries include members that may, alone or in combination, perform specified operations when operating. Circuitry members are flexible over time and subject to underlying hardware variability. In an example, hardware of the circuitry may be immutably designed to carry out a specific operation (e.g., hardwired). In another example, the hardware comprising the circuitry may include variably connected physical components (e.g., execution units, transistors, simple circuits, etc.), including a computer-readable medium physically modified (e.g., magnetically, electrically, such as via a change in physical state or transformation of another physical characteristic, etc.) to encode instructions of the specific operation.

As per present disclosure, connecting the physical components of the control circuitry, the underlying electrical properties of a hardware constituent may be changed, for example, from an insulating characteristic to a conductive characteristic or vice versa. The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry.

The computer readable storage medium as per the present disclosure, provides a tangible and practical implementation of the automated inspection method, making it easier to integrate into existing inspection systems. The computer readable storage medium ensures that the inspection method can be easily and consistently replicated across multiple inspection systems, leading to standardized quality control procedures. The processor-executable instructions provide the flexibility to update or modify the inspection method through software changes rather than hardware, allowing for rapid adaptation to new inspection requirements or improvements in inspection technology. Furthermore, the automation of the inspection process through the use of processor-executable instructions can significantly reduce the potential for human error, increase inspection speed, and enable continuous operation, which is critical for maintaining high production rates in semiconductor manufacturing.

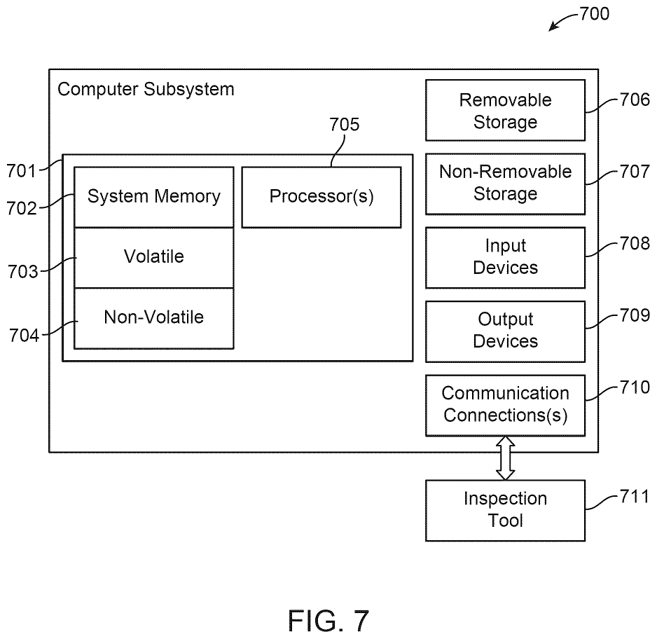

FIG. 7, illustrates an example computer system storing processor-executable instructions is further configured to execute the method of automated inspection of a microfabricated feature on a substrate using the inspection tool 711 (or apparatus). The method of automated inspection of a microfabricated feature on a substrate is executed by a control circuitry which is implemented as computer subsystem.

The computer subsystem 700 of FIG. 7, is configured to provide the functionality described herein. In embodiments, the computer subsystem 700 can be a server and/or other computing device that performs the operations discussed herein, such as the classifying defect operations as described herein. The computer subsystem 700 may include computing components 701. The computing components 701 can include at least one processor 705 and system memory 702. The system memory 702 may include a non-transient computer readable medium. Depending on the exact configuration, system memory 702 (storing, among other things, substrate yield prediction instructions and instructions to perform the other operations disclosed herein) can be volatile (such as RAM), non-volatile (such as ROM, flash memory, etc.), or some combination thereof.

The system memory 702 may store one or more sets of data structures or instructions (e.g., software or firmware) embodying or utilized by any one or more of the techniques or functions described herein. The instructions may also reside, completely or at least partially, within a main memory, within a volatile memory 703, within a non-volatile memory 704, or within the hardware-based processor 705 during execution thereof by the computer subsystem 700. In an example, one or any combination of the hardware-based processor 705, the main memory 702, the volatile memory 703, and the non-volatile memory 704 may constitute computer-readable media. While the computer-readable medium is considered as a single medium, the term “computer-readable medium” may include a single medium or multiple media (e.g., a centralized or distributed database, and/or associated caches and servers) configured to store the one or more instructions.

Further, the computer subsystem 700 may also include storage devices (removable 706, and/or non-removable 707) including, but not limited to, solid-state devices, magnetic or optical disks, or tape. Further, the computer subsystem 700 may also have input device(s) 708 such as touch screens, keyboard, mouse, pen, voice input, etc., and/or output device(s) 709 such as a display, speakers, printer, etc. One or more communication connections 710, such as local-area network (LAN), wide-area network (WAN), point-to-point, Bluetooth, RF, etc., may also be incorporated into the computer subsystem 700. While only a single computer subsystem is illustrated, the term “computer subsystem” shall also be taken to include any collection of computer subsystems that individually or jointly execute a set (or multiple sets) of instructions to perform any one or more of the methodologies discussed herein, such as cloud computing, software as a service (SaaS), or other computer cluster configurations.

The embodiments described herein may be employed using software, hardware, or a combination of software and hardware to implement and perform the systems and methods disclosed herein. Although specific devices have been recited throughout the disclosure as performing specific functions, one of skill in the art will appreciate that these devices are provided for illustrative purposes, and other devices may be employed to perform the functionality disclosed herein without departing from the scope of the disclosure. In addition, some aspects of the present disclosure are described above with reference to block diagrams and/or operational illustrations of systems and methods according to aspects of this disclosure. The functions, operations, and/or acts noted in the blocks may occur out of the order that is shown in any respective flowchart. For example, two blocks shown in succession may in fact be executed or performed substantially concurrently or in reverse order, depending on the functionality and implementation involved.

This disclosure describes some embodiments of the present technology with reference to the accompanying drawings, in which only some of the possible embodiments were shown. Other aspects may, however, be embodied in many different forms and should not be construed as limited to the embodiments set forth herein. Rather, these embodiments were provided so that this disclosure was thorough and complete and fully conveyed the scope of the possible embodiments to those skilled in the art. Further, as used herein and in the claims, the phrase “at least one of element A, element B, or element C” is intended to convey any of: element A, element B, element C, elements A and B, elements A and C, elements B and C, and elements A, B, and C. Further, one having skill in the art will understand the degree to which terms such as “about” or “substantially” convey in light of the measurement techniques utilized herein. To the extent such terms may not be clearly defined or understood by one having skill in the art, the term “about” shall mean plus or minus ten percent.

Although specific embodiments are described herein, the scope of the technology is not limited to those specific embodiments. Moreover, while different examples and embodiments may be described separately, such embodiments and examples may be combined with one another in implementing the technology described herein. One skilled in the art will recognize other embodiments or improvements that are within the scope and spirit of the present technology. Therefore, the specific structure, acts, or media are disclosed only as illustrative embodiments. The scope of the technology is defined by the following claims and any equivalents therein.

What is claimed is:

1. A method of automated inspection of a microfabricated feature on a substrate using a polarization selected to improve fluorescence emission, the method comprising:
loading the substrate into an inspection tool having a laser source;
selecting a polarization of laser light emitted by the laser source based on the microfabricated features on the substrate;
irradiating the microfabricated feature with the laser light from the laser source; and
use collected fluorescence emission emitted by the microfabricated feature in response to being irradiated with the laser light from the laser source to form an image of the microfabricated features.

2. The method of claim 1, wherein selecting the polarization of the laser light comprises adjusting a half-waveplate and a quarter-waveplate between the laser source and the substrate to impart a desired type of polarization to the laser light.

3. The method of claim 2, wherein the desired type of polarization comprises adjusting a polarization manipulator to impart elliptical polarization to the laser light.

4. The method of claim 2, wherein the desired type of polarization comprises to substantially align the polarization of the laser light with the microfabricated feature.

5. The method of claim 2, wherein the microfabricated feature comprises a plurality of substantially parallel lines separated by a spacing of less than approximately 2 microns.

6. The method of claim 1, further comprising determining a polarization of the laser light based on at least an alignment of the microfabricated feature.

7. The method of claim 6, wherein determining the polarization of the laser light is determined using an image of the microfabricated feature prior to loading the substrate.

8. The method of claim 6, wherein determining the polarization of the laser light is performed during recipe creation.

9. An inspection tool for automated inspection of a microfabricated feature on a substrate using a polarization selected to improve fluorescence emission, the inspection tool comprising:
means for selecting a polarization of laser light emitted by the laser source based on the microfabricated features on the substrate;
means for irradiating the microfabricated feature with the laser light from the laser source; and
means for using collected fluorescence emission emitted by the microfabricated feature in response to being irradiated with the laser light from the laser source to form an image of the microfabricated features.

10. The computer readable storage medium of claim 9, wherein selecting the polarization of the laser light comprises adjusting a half-waveplate and a quarter-waveplate between the laser source and the substrate to impart a desired type of polarization to the laser light.

11. The computer readable storage medium of claim 10, wherein selecting the desired type of polarization is elliptical polarization of the laser light.

12. The computer readable storage medium of claim 9, wherein selecting the polarization of the laser light comprises looking at instructions to determine a type of polarization.

13. An apparatus for automated inspection of a microfabricated feature on a substrate using a polarization selected to improve fluorescence emission, the apparatus comprising:
a stage for holding the substrate;
a laser source;
control circuitry configured to:
select a polarization of laser light emitted by the laser source based on the microfabricated features on the substrate; and
control irradiation of the microfabricated feature with the laser light from the laser source; and
a detector configured to collect fluorescence emission emitted by the microfabricated feature in response to being irradiated with the laser light from the laser source to form an image of the microfabricated features.

14. The apparatus of claim 13, wherein selecting the polarization of the laser light comprises adjusting a half-waveplate and a quarter-waveplate between the laser source and the substrate to impart a desired type of polarization to the laser light.

15. The apparatus of claim 14, wherein the desired type of polarization for the laser light is elliptically polarized.

16. The apparatus of claim 13, wherein the desired type of polarization for the laser light is to substantially align the polarization of the laser light with the microfabricated feature.

17. The apparatus of claim 13, wherein the microfabricated feature comprises a plurality of substantially parallel lines separated by a spacing of less than approximately 2 microns.

18. The apparatus of claim 13, wherein the control circuitry is configured to select the polarization of the laser light in dependence on an indication of an alignment of the microfabricated feature.

19. The apparatus of claim 18, wherein the control circuitry is configured to receive the indication of the alignment of the microfabricated feature as an image of the microfabricated feature.

20. The apparatus of claim 18, wherein the control circuitry is configured to receive the indication of the alignment of the microfabricated feature as a feature description loaded into the apparatus.
